(19) United States
(12) Patent Application Publication
(10) Pub. No.: US 2015/0147696 A1
(43) Pub. Date: May 28, 2015

(54) METHOD FOR PRODUCING POLYMER COMPOUND, POLYMER COMPOUND, AND PHOTORESIST RESIN COMPOSITION

(71) Applicant: DAICEL CORPORATION, Osaka-shi, Osaka (JP)

(72) Inventors: Akira Eguchi, Himeji-shi (JP); Masamichi Nishimura, Himeji-shi (JP)

(73) Assignee: DAICEL CORPORATION, Osaka-shi, Osaka (JP)

(21) Appl. No.: 14/412,111

(22) PCT Filed: Jul. 26, 2013
(86) PCT No.: PCT/JP2013/070289

§ 371 Date: Dec. 30, 2014

(30) Foreign Application Priority Data
Aug. 7, 2012 (JP) 2012-175428

(51) Int. Cl. G03F 7/004; C08F 28/06; C08F 22/04; C08F 24/00

(52) U.S. Cl. CPC G03F 7/004; C08F 24/00; C08F 28/06; C08F 22/04
USPC 430/285.1; 526/270; 526/257; 526/271; 526/242

(57) ABSTRACT

Provided is a method for producing a polymer compound that has very low contents of impurities such as metal components and exhibits excellent storage stability. The production method gives such a polymer compound. The polymer compound is incorporated into a photoresist resin composition.

The method for producing a polymer compound includes the step of filtering a resin solution containing a polymer compound through a filter. The filter is approximately devoid of strongly acidic cation-exchange groups and develops a positive zeta potential. The polymer compound includes a monomer unit (a) and a monomer unit (b). The monomer unit (a) includes at least one monomer units represented by Formulae (a1) to (a3). The monomer unit (b) contains a group capable of releasing a moiety thereof by the action of an acid to develop solubility in an alkali.

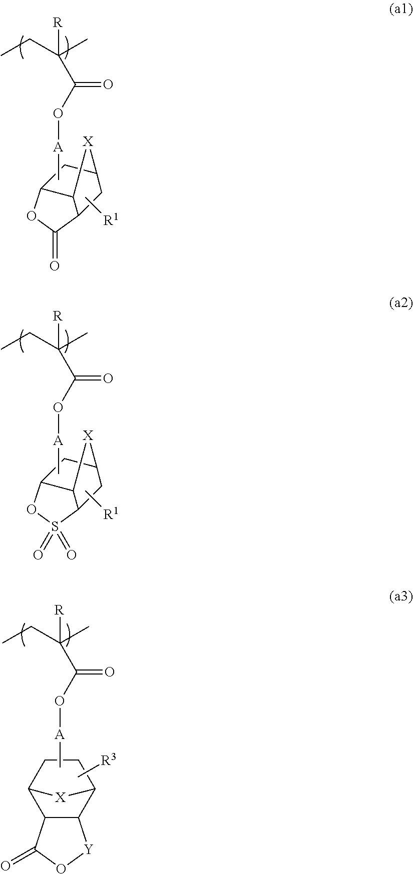

### TECHNICAL FIELD

The present invention relates to methods for producing polymer compounds that are used typically in semiconductor micromachining, polymer compounds produced by the production methods, and photoresist resin compositions containing the polymer compounds.

### BACKGROUND ART

Positive photoresists for use in production of semiconductor devices generally include a resist polymer acting as a base resin, a photoacid generator, an organic solvent, and some kinds of additives as needed. The positive photoresists require properties such as a property of developing alkali-solubility in an irradiated portion upon photoirradiation, as well as adhesion to a silicon wafer and plasma etch resistance.

With finer design rules of semiconductor integrated circuits, exposing sources with shorter and shorter wavelengths have been used in photolithography. The exposing sources are now moving from KrF excimer laser with a wavelength of 248 nm to ArF excimer laser with a wavelength of 193 nm. Proposed resist polymers for use in ArF excimer laser exposure include various polymers such as those including a constitutional repeating unit containing a lactone skeleton offering satisfactory adhesion to a substrate and/or a constitutional repeating unit containing an alicyclic hydrocarbon skeleton offering excellent etch resistance.

Such a resist polymer is generally prepared by polymerizing a monomer mixture; and isolating the target polymer by a precipitation operation. Disadvantageously, however, the polymer obtained in this manner contains metal components, such as sodium and iron, derived typically from raw materials, production equipment, and environment. The resulting polymer, when used in a photoresist to produce, for example, a semiconductor device, may cause the semiconductor device to have inferior electrical properties.

The metal components are removed typically by a known method of filtrating a reaction mixture through a filter containing a strongly acidic cation-exchange group (Patent Literature (PTL) 1 to 3). The filtering method can remove the metal components. Unfortunately, however, the resulting resist polymer filtrated through the filter has poor storage stability and fails to form a satisfactory resist film.

### CITATION LIST

### Patent Literature

PTL 1: Japanese Patent No. 3363051
PTL 2: Japanese Unexamined Patent Application Publication (JP-A) No. 2006-37117
PTL 3: JP-A No. 2007-291387

### SUMMARY OF INVENTION

### Technical Problem

Accordingly, it is an object of the present invention to provide a method for producing a polymer compound that has very low contents of impurities such as metal components and exhibits excellent storage stability. It is another object of the present invention to provide a polymer compound produced by the production method. It is still another object of the present invention to provide a photoresist resin composition containing the polymer compound.

### Solution to Problem

After intensive investigations to achieve the objects, the present inventors have found as follows. Assume that a polymer compound includes a moiety that is susceptible to hydrolysis, such as a lactone (in particular, lactone containing one or more electron-withdrawing groups such as cyano and trifluoromethyl), sultone, and/or acid anhydride moiety. When this polymer compound is filtered through a filter containing a strongly acidic cation-exchange group, the lactone (in particular, lactone containing one or more electron-withdrawing groups such as cyano and trifluoromethyl), sultone, or acid anhydride moiety is partially hydrolyzed. This acts as a trigger for the leaving of acid-leaving groups in the polymer compound with time and causes the polymer compound to have inferior resist performance. The present inventors have also found as follows. Assume that the polymer compound is filtered through a filter that is approximately devoid of strongly acidic cation-exchange groups and develops a positive zeta potential with respect to the charged polymer compound to be filtered. In this case, the filter can adsorb metal components and remove them from the polymer compound without causing the hydrolysis of the lactone (in particular, lactone containing one or more electron-withdrawing groups such as cyano and trifluoromethyl), sultone, or acid anhydride moiety. This allows the production of a polymer compound that exhibits excellent storage stability. The polymer compound in turn enables production of a semiconductor device having excellent electrical properties. The present invention has been made based on these findings.

Specifically, the present invention provides, in one aspect, a method for producing a polymer compound. The method includes the step of filtering a resin solution containing a polymer compound through a filter. The filter is approximately devoid of strongly acidic cation-exchange groups and develops a positive zeta potential. The polymer compound includes a monomer unit (a) and a monomer unit (b). The monomer unit (b) contains a group capable of releasing a moiety thereof by the action of an acid to develop solubility in an alkali. The monomer unit (a) includes at least one monomer unit selected from the group consisting of monomer units represented by Formulae (a1) to (a3):

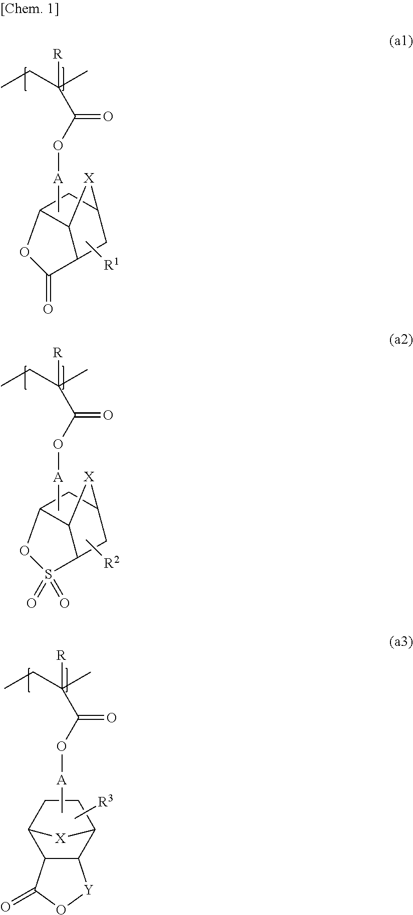

where R is, independently in each occurrence, selected from hydrogen, halogen, and optionally halogenated C₁-C₆ alkyl; A is, independently in each occurrence, selected from a single bond and a linkage group; X is, independently in each occurrence, selected from non-bond, methylene, ethylene, oxygen, and sulfur; Y is selected from methylene and carbonyl; and R¹ to R³ are, identically or differently, selected from hydrogen, fluorine, optionally fluorinated alkyl, optionally protected hydroxyl, optionally protected hydroxyalkyl, optionally protected carboxy, and cyano.

The resin solution undergone the filtering step preferably has a sodium content (based on resin solids content) of 20 ppb or less and an iron content (based on resin solids content) of 10 ppb or less.

In the production method, times Tₒ and T₁ specified as follows preferably meet a condition specified by formula:

T₀−T₁≦80

where T₀ represents a time taken for the resin solution before subjected to the filtering step to have an acid value of greater than 0.05 mmol/g upon heating at 60° C.; and T₁ represents a time taken for the resin solution after subjected to the filtering step to have an acid value of greater than 0.05 mmol/g upon heating at 60° C.

The monomer unit (b) preferably includes at least one monomer unit selected from the group consisting of monomer units represented by Formulae (b1) to (b4):

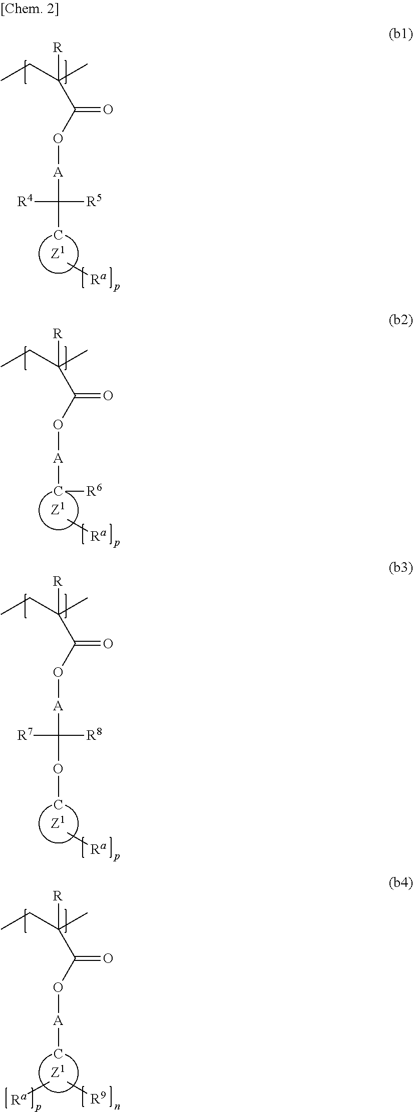

where R is, independently in each occurrence, selected from hydrogen, halogen, and optionally halogenated C₁-C₆ alkyl; A is, independently in each occurrence, selected from a single bond and a linkage group; R⁴ to R⁶ represent, identically or differently, optionally substituted C₁-C₆ alkyl; R⁷ and R⁸ are, identically or differently, selected from hydrogen and optionally substituted C₁-C₆ alkyl; R⁹ represents, independently in each occurrence, a —COOR^{c} group, where R^{c} is, independently in each occurrence, selected from an optionally substituted tertiary hydrocarbon group, tetrahydrofuranyl, tetrahydropyranyl, and oxepanyl; n represents an integer of from 1 to 3; R^{a} is a substituent bonded to Ring Z¹ and is, independently in each occurrence, selected from oxo, alkyl, optionally protected hydroxyl, optionally protected hydroxyalkyl, and optionally protected carboxy; p represents, independently in each occurrence, an integer of from 0 to 3, where, when p is 2 or 3, two or three occurrences of R^{a} may be identical or different; and Ring Z¹ represents, independently in each occurrence, a C₃-C₂₀ alicyclic hydrocarbon ring.

The polymer compound herein preferably further includes, in addition to the monomer units (a) and (b), a monomer unit (c) represented by Formula (c1):

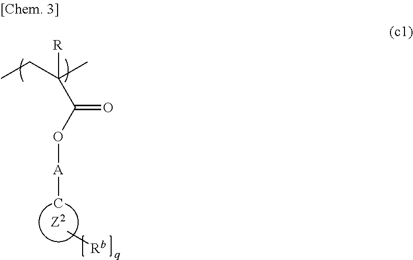

where R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

The present invention provides, in another aspect, a polymer compound produced by the method for producing a polymer compound.

The polymer compound may have a weight-average molecular weight of from 1000 to 50000 and a molecular weight distribution of from 1.0 to 3.0, where the molecular weight distribution is a ratio of the weight-average molecular weight to a number-average molecular weight.

In addition and advantageously, the present invention provides a photoresist resin composition including the polymer compound, a photoacid generator, and an organic solvent.

### Advantageous Effects of Invention

By the method for producing a polymer compound according to the present invention, a polymer compound prepared by polymerizing a monomer mixture undergoes filtration treatment using a filter. The filter is approximately devoid of strongly acidic cation-exchange groups and develops a positive zeta potential with respect to the polymer compound. This removes sodium, iron, and other metal components and still inhibits an acid-leaving group in the polymer compound from leaving with time, where the metal components cause deterioration in electrical properties typically of semiconductor devices. The method can produce a polymer compound that exhibits excellent storage stability and has very low contents of metal components such as sodium and iron. The leaving of the acid-leaving group is triggered by partial hydrolysis of a polar group in the polymer compound. The polar group is exemplified by lactone (in particular, lactone containing one or more electron-withdrawing groups such as cyano and trifluoromethyl), sultone (—S(═O)₂—O—), and acid anhydride (—C(═O)—O—C(═O)—) moieties or groups.

The polymer compound according to the present invention exhibits excellent storage stability, has very low contents of metal components such as sodium and iron, and is advantageously usable as a resist polymer for ArF exposure. The polymer compound according to the present invention enables the production of a semiconductor device having excellent electrical properties.

### DESCRIPTION OF EMBODIMENTS

Polymer Compound

The polymer compound according to the present invention includes a monomer unit (a) and a monomer unit (b). The monomer unit (b) contains a group capable of releasing a moiety thereof by the action of an acid to develop solubility in an alkali. The polymer compound according to the present invention may further include a monomer unit (c) in addition to the monomer units (a) and (b).

Monomer Unit (a)

The monomer unit (a) includes an alicyclic skeleton containing at least one of [—C(═O)—O—], [—S(═O)₂—O—], and [—C(═O)—O—C(═O)—] as a polar group. The monomer unit (a) imparts substrate adhesion and etch resistance to the polymer compound.

The monomer unit (a) includes at least one monomer unit selected from the group consisting of monomer units represented by Formulae (a1) to (a3). In the formulae, R is, independently in each occurrence, selected from hydrogen, halogen, and optionally halogenated C₁-C₆ alkyl. “A” is, independently in each occurrence, selected from a single bond and a linkage group. X is, independently in each occurrence, selected from non-bond, methylene, ethylene, oxygen, and sulfur. Y is selected from methylene and carbonyl. R¹ to R³ are, identically or differently, selected from hydrogen, fluorine, optionally fluorinated alkyl, optionally protected hydroxyl, optionally protected hydroxyalkyl, optionally protected carboxy, and cyano.

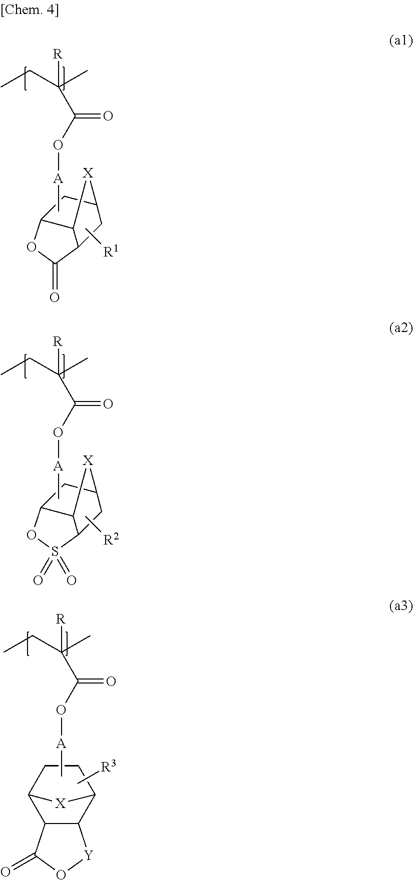

In Formulae (a1) to (a3), R is, independently in each occurrence, selected from hydrogen, halogen, and optionally halogenated C₁-C₆ alkyl. The halogen is exemplified by chlorine, bromine, and iodine. The C₁-C₆ alkyl is exemplified by methyl, ethyl, propyl, isopropyl, butyl, isobutyl, s-butyl, t-butyl, pentyl, isoamyl, s-amyl, t-amyl, and hexyl. The halogenated C₁-C₆ alkyl is exemplified by C₁-C₆ haloalkyl such as trifluoromethyl and 2,2,2-trifluoroethyl. The haloalkyl is a group corresponding to the alkyl, except with one or more hydrogen atoms constituting the alkyl being substituted by halogen atoms.

In Formulae (a1) to (a3), A is, independently in each occurrence, selected from a single bond and a linkage group. The linkage group is exemplified by alkylene, carbonyl (—C(═O)—), ether bond (—O—), ester bond (—C(═O)—O—), amide bond (—C(═O)—NH—), carbonate bond (—O—C(═O)—O—), and groups each including two or more of them linked to each other. The alkylene is exemplified by linear or branched chain alkylene such as methylene, methylmethylene, dimethylmethylene, ethylene, propylene, and trimethylene; and divalent alicyclic hydrocarbon groups such as 1,2-cyclopentylene, 1,3-cyclopentylene, cyclopentylidene, 1,2-cyclohexylene, 1,3-cyclohexylene, 1,4-cyclohexylene, and cyclohexylidene, of which cycloalkylene and cycloalkylidene are preferred.

The alkyl as R¹ to R³ is exemplified by C₁-C₆ alkyl such as methyl, ethyl, propyl, isopropyl, butyl, s-butyl, t-butyl, pentyl, isoamyl, s-amyl, t-amyl, and n-hexyl.

The fluorinated alkyl as R¹ to R³ is exemplified by C₁-C₆ fluoroalkyl such as trifluoromethyl and 2,2,2-trifluoroethyl. The fluoroalkyl is a group corresponding to the alkyl, except with one or more hydrogen atoms constituting the alkyl being substituted by fluorine atoms.

The hydroxyalkyl as R¹ to R³ is exemplified by C₁-C₆ hydroxyalkyl such as hydroxymethyl, 2-hydroxyethyl, 1-hydroxyethyl, 3-hydroxypropyl, 2-hydroxypropyl, 4-hydroxybutyl, and 6-hydroxyhexyl.

The hydroxyl and the hydroxyalkyl may each be protected by a protecting group. The protecting group herein is exemplified by C₁-C₄ alkyl such as methyl, ethyl, and t-butyl; groups each forming an acetal bond with oxygen constituting the hydroxyl, such as methoxymethyl and other (C₁-C₄ alkyl)-O—(C₁-C₄ alkyl); and groups each forming an ester bond with oxygen constituting the hydroxyl, such as acetyl and benzoyl.

The carboxy as R¹ to R³ may be protected by a protecting group. The protecting group is exemplified by C₁-C₆ alkyl such as methyl, ethyl, propyl, isopropyl, butyl, s-butyl, t-butyl, pentyl, isoamyl, s-amyl, t-amyl, and hexyl; and other protecting groups such as 2-tetrahydrofuranyl, 2-tetrahydropyranyl, and 2-oxepanyl.

Of the monomer units (a), preferred are a monomer unit (a1) represented by Formula (a1) in which R¹ is an electron-withdrawing group such as cyano or C₁-C₆ fluoroalkyl; the monomer unit (a2) represented by Formula (a2); and a monomer unit (a3) represented by Formula (a3) in which Y is carbonyl. These monomer units can impart excellent substrate adhesion and etch resistance to the polymer compound, develop excellent solubility in an alkaline developer, and contribute to the formation of a fine pattern with high precision.

Specifically, the monomer unit (a) for use in the present invention is exemplified by monomer units represented by formulae below. The monomer unit (a) may be incorporated into the polymer compound by subjecting a corresponding unsaturated carboxylic acid ester to polymerization.

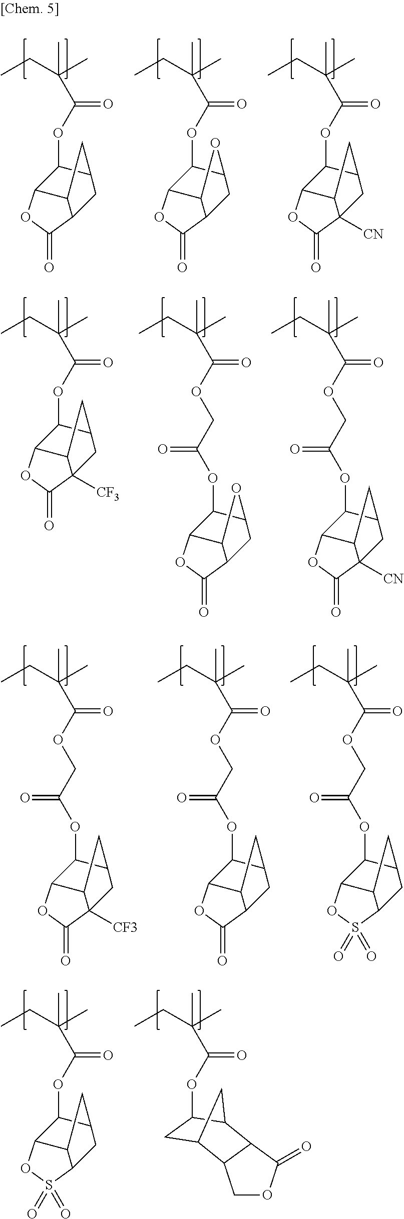

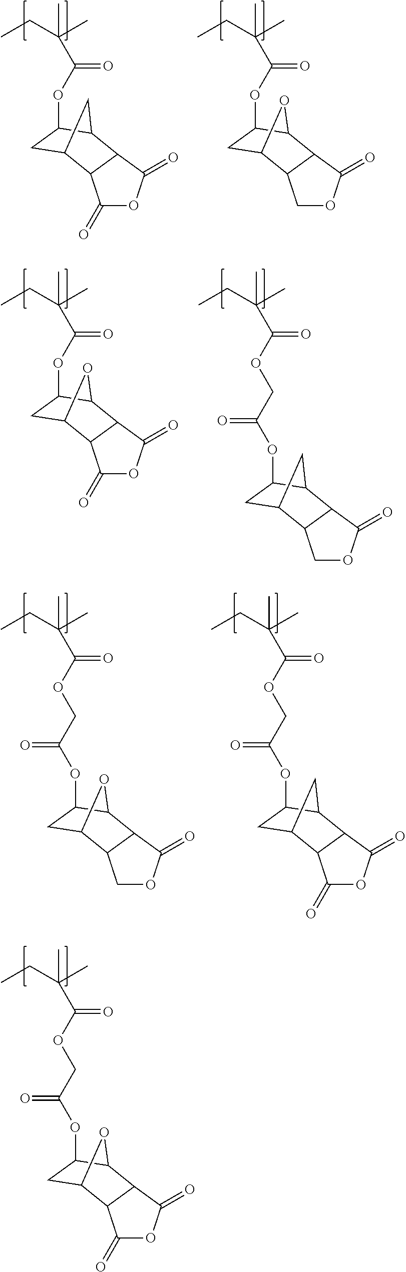

Monomer Unit (b)

The monomer unit (b) for use herein contains a group capable of releasing a moiety thereof by the action of an acid to develop solubility in an alkali. The monomer unit (b) imparts, to the polymer compound, etch resistance and a property of becoming alkali-soluble by the action of an acid. The monomer unit (b) for use herein preferably includes at least one monomer unit selected from the group consisting of monomer units represented by Formulae (b1) to (b4) below.

In Formulae (b1) to (b4), R is, independently in each occurrence, selected from hydrogen, halogen, and optionally halogenated C₁-C₆ alkyl. “A” is, independently in each occurrence, selected from a single bond and a linkage group. R⁴ to R⁶ represent, identically or differently, optionally substituted C₁-C₆ alkyl. R⁷ and R⁸ are, identically or differently, selected from hydrogen and optionally substituted C₁-C₆ alkyl. R⁹ represents, independently in each occurrence, a —COOR^{c} group, where R^{c} is, independently in each occurrence, selected from an optionally substituted tertiary hydrocarbon group, tetrahydrofuranyl, tetrahydropyranyl, and oxepanyl. The repetition number n represents an integer of from 1 to 3. R^{a} is a substituent bonded to Ring Z¹ and is, independently in each occurrence, selected from oxo, alkyl, optionally protected hydroxyl, optionally protected hydroxyalkyl, and optionally protected carboxy. The repetition number p represents, independently in each occurrence, an integer of from 0 to 3. Ring Z¹ represents, independently in each occurrence, a C₃-C₂₀ alicyclic hydrocarbon ring.

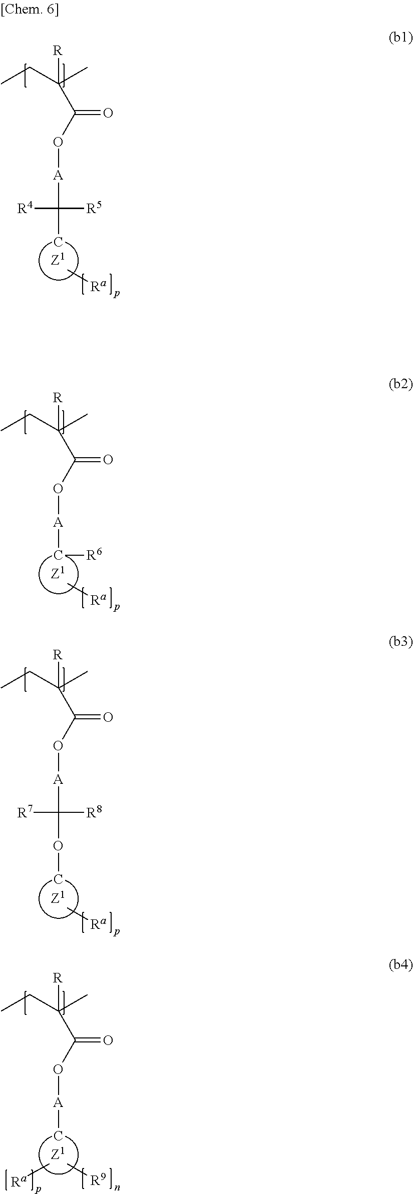

R and A in Formulae (b1) to (b4) are exemplified as with R and A in Formulae (a1) to (a3). The alkyl, optionally protected hydroxyl, optionally protected hydroxyalkyl, and optionally protected carboxy as R^{a} in Formulae (b1) to (b4) are exemplified as with those in R¹ to R³ in Formulae (a1) to (a3). When p is 2 or 3, two or three occurrences of R^{a} may be identical or different.

The C₁-C₆ alkyl as R⁴ to R⁸ is exemplified by linear or branched chain alkyl such as methyl, ethyl, propyl, isopropyl, butyl, isobutyl, s-butyl, t-butyl, pentyl, isoamyl, s-amyl, t-amyl, and hexyl. Among them, C₁-C₄ alkyl is preferred, C₁-C₃ alkyl is particularly preferred, and C₁-C₂ alkyl is most preferred herein.

The C₁-C₆ alkyl as R⁴ to R⁸ may be substituted with one or more substituents. The substituents are exemplified by halogen, hydroxy, substituted hydroxy (e.g., C₁-C₄ alkoxy such as methoxy, ethoxy, and propoxy), and cyano. Specifically, the substituted C₁-C₆ alkyl is exemplified by C₁-C₆ haloalkyl such as trifluoromethyl and 2,2,2-trifluoroethyl, where the C₁-C₆ haloalkyl is a group corresponding to the alkyl, except with one or more hydrogen atoms constituting the alkyl being substituted by halogen atoms; and other substituted alkyl such as hydroxymethyl, 2-hydroxyethyl, methoxymethyl, 2-methoxyethyl, ethoxymethyl, 2-ethoxyethyl, cyanomethyl, and 2-cyanoethyl.

The tertiary hydrocarbon group as R^{c} is exemplified by t-butyl and t-pentyl.

The tertiary hydrocarbon group as R^{c} may be substituted with one or more substituents. The substituents are exemplified by halogen, hydroxy, substituted hydroxy (e.g., C₁-C₄ alkoxy such as methoxy, ethoxy, and propoxy), and cyano.

The C₃-C₂₀ alicyclic hydrocarbon ring as Ring Z¹ is exemplified by monocyclic alicyclic carbon rings including cycloalkane rings containing 3 to about 20 members, such as cyclopropane, cyclobutane, cyclopentane, cyclohexane, and cyclooctane rings (of which those containing 3 to about 15 members are preferred, and those containing about 5 to about 12 members are particularly preferred), and cycloalkene rings containing 3 to about 20 members, such as cyclopropene, cyclobutene, cyclopentene, and cyclohexene rings (of which those containing 3 to about 15 members are preferred, and those containing about 5 to about 10 members are more preferred); adamantane ring; rings containing a norbornane or norbornene ring, such as norbornane, norbornene, bornane, isobornane, tricyclo[5.2.1.0^{2,6}]decane, and tetracyclo[4.4.0.1^{2,5}.1^{7,10}]dodecane rings; rings corresponding to polycyclic aromatic fused rings, except for being hydrogenated, such as perhydroindene, decahydronaphthalene (perhydronaphthalene), perhydrofluorene (tricyclo[7.4.0.0^{3,8}]tridecane), and perhydroanthracene rings, of which fully hydrogenated rings are preferred; and bridged carbon rings containing 2 to about 6 rings. The bridged carbon rings are exemplified by tricyclo[4.2.2.1^{2,5}]undecane ring and other bicyclic, tricyclic, or tetracyclic bridged carbon rings (e.g., bridged carbon rings containing about 6 to about 20 carbon atoms).

Specifically, the monomer unit (b) for use herein is exemplified by monomer units represented by formulae as follows. The monomer unit (b) may be incorporated into the polymer compound by subjecting a corresponding unsaturated carboxylic acid ester to polymerization.

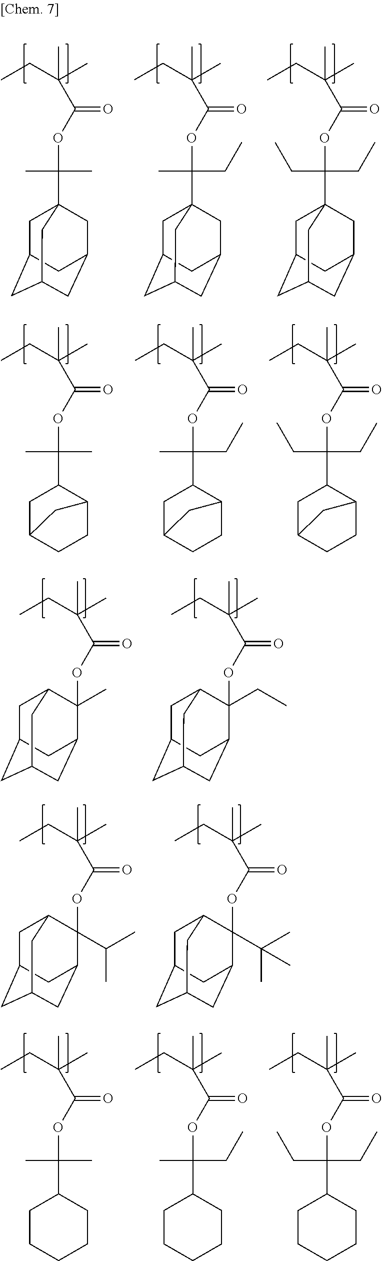

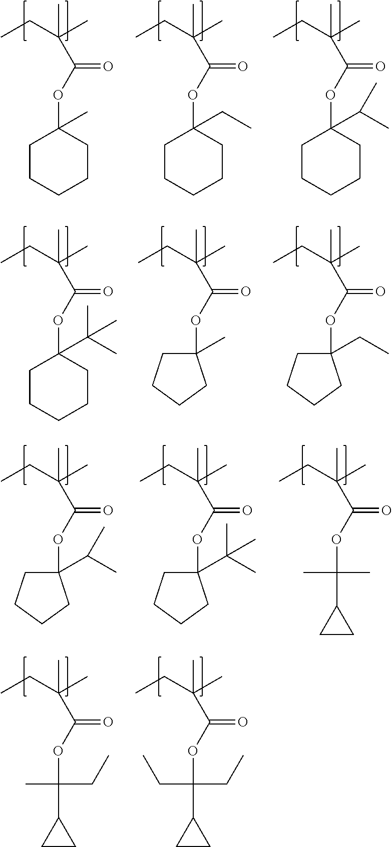

Monomer Unit (c)

The monomer unit (c) for use herein is represented by Formula (c1) and imparts high transparency and etch resistance to the polymer compound. In the formula, R is selected from hydrogen, halogen, and optionally halogenated C₁-C₆ alkyl. “A” is selected from a single bond and a linkage group. R^{b} is, independently in each occurrence, selected from optionally protected hydroxyl, optionally protected hydroxyalkyl, optionally protected carboxy, and cyano. The repetition number q represents an integer of from 1 to 5. Ring Z² represents a C₆-C₂₀ alicyclic hydrocarbon ring.

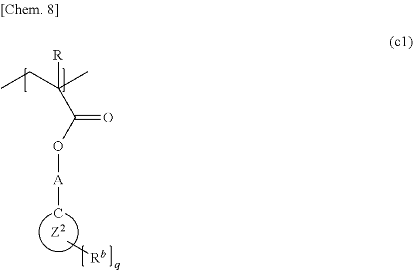

R and A in Formula (c1) are exemplified as with R and A in Formulae (a1) to (a3). The optionally protected hydroxyl, optionally protected hydroxyalkyl, and optionally protected carboxy as R^{b} in Formula (c1) are exemplified as with those in R² to R³ in Formulae (a1) to (a3). When q is an integer of from 2 to 5, two to five occurrences of R^{b} may be identical or different.

The Ring Z² in Formula (c1) represents a C₆-C₂₀ alicyclic hydrocarbon ring. The Ring Z² is exemplified by monocyclic alicyclic carbon rings including cycloalkane rings containing about 6 to about 20 members, such as cyclohexane and cyclooctane rings (of which those containing about 6 to about 15 members are preferred, and those containing about 6 to about 12 members are particularly preferred), and cycloalkene rings containing about 6 to about 20 members, such as cyclohexene ring (of which those containing about 6 to about 15 members are preferred, and those containing about 6 to about 10 members are particularly preferred; adamantane ring; rings containing a norbornane or norbornene ring, such as norbornane, norbornene, bornane, isobornane, tricyclo[5.2.1.0^{2,6}]decane, and tetracyclo[4.4.0.1^{2,5}.1^{7,10}]dodecane rings; rings corresponding to polycyclic aromatic fused rings, except for being hydrogenated, such as perhydroindene, decahydronaphthalene (perhydronaphthalene), perhydrofluorene (tricyclo[7.4.0.0^{3,8}]tridecane), and perhydroanthracene rings, of which fully hydrogenated rings are preferred; and bridged carbon rings containing 2 to about 6 rings. The bridged carbon rings are exemplified by tricyclo[4.2.2.1^{2,5}]undecane ring and other bicyclic, tricyclic, or tetracyclic bridged carbon rings (e.g., bridged carbon rings containing about 6 to about 20 carbon atoms).

Specifically, the monomer unit (c) for use herein is exemplified by monomer units represented by formulae below. The monomer unit (c) may be incorporated into the polymer compound by subjecting a corresponding unsaturated carboxylic acid ester to polymerization.

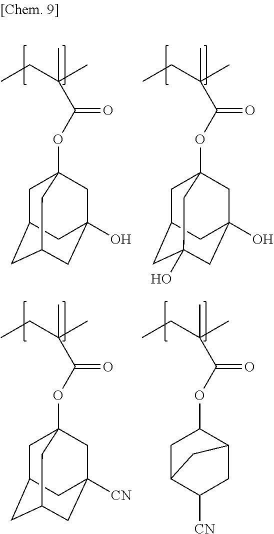

The polymer compound according to the present invention may contain the monomer unit (a) in a content of typically from about 5 to about 95 mole percent, preferably from 10 to 90 mole percent, particularly preferably from 20 to 80 mole percent, and most preferably from 30 to 70 mole percent, based on the amount of total monomer units constituting the polymer compound. The polymer compound may contain the monomer unit (b) in a content of typically from about 5 to about 95 mole percent, preferably from 10 to 90 mole percent, particularly preferably from 20 to 80 mole percent, and most preferably from 30 to 70 mole percent, based on the amount of total monomer units constituting the polymer compound. The polymer compound may contain the monomer unit (c) in a content of typically about 40 mole percent or less, preferably 30 mole percent or less, particularly preferably 20 mole percent or less, based on the amount of total monomer units constituting the polymer compound.

The polymer compound according to the present invention may have a weight-average molecular weight (Mw) of typically from about 1000 to about 50000, preferably from 3000 to 20000, and particularly preferably from 4000 to 15000 and a molecular weight distribution of typically from about 1.0 to about 3.0 and preferably from 1.0 to 2.5. The molecular weight distribution is the ratio (Mw/Mn) of the weight-average molecular weight Mw to a number-average molecular weight Mn. The Mn and Mw are both values calibrated with a polystyrene standard.

Method for Producing Polymer Compound

The method for producing a polymer compound according to an embodiment of the present invention includes the step of filtering a resin solution containing the polymer compound using a filter, where the filter is approximately devoid of strongly acidic cation-exchange groups and develops a positive zeta potential, and the polymer compound includes the monomer units (a) and (b). This step is hereinafter also simply referred to as “filtering step”.

The polymer compound to be subjected to the filtering step may be produced through the step of polymerizing a monomer mixture. The monomer mixture includes unsaturated carboxylic acid esters respectively corresponding to the monomer units (a) and (b), and, as needed, an unsaturated carboxylic acid ester corresponding to the monomer unit (c). The step of polymerizing may be performed by a common process for use in production typically of acrylic polymers, such as solution polymerization, bulk polymerization, suspension polymerization, bulk-suspension polymerization, and emulsion polymerization. Among them, solution polymerization is preferred, of which dropping polymerization is particularly preferred.

Specifically, the dropping polymerization may be performed by any of processes (i) to (iv) as follows. In the process (i), the monomers are dissolved in an organic solvent to give a monomer solution. Separately, a polymerization initiator is dissolved in an organic solvent to give a polymerization initiator solution. The prepared monomer solution and polymerization initiator solution are individually added dropwise to an organic solvent held at a constant temperature. In the process (ii), the monomers and a polymerization initiator are dissolved in an organic solvent to give a mixture solution. The mixture solution is added dropwise to an organic solvent held at a constant temperature. In the process (iii), the monomers are dissolved in an organic solvent to give a monomer solution. Separately, a polymerization initiator is dissolved in an organic solvent to give a polymerization initiator solution. The prepared polymerization initiator solution is added dropwise to the monomer solution held at a constant temperature. In the process (iv), part of the monomers is dissolved in an organic solvent to give a monomer solution 1. The remainder of the monomers is dissolved in an organic solvent to give a monomer solution 2. A polymerization initiator is dissolved in an organic solvent to give a polymerization initiator solution. The prepared monomer solution 2 and polymerization initiator solution are added dropwise to the monomer solution 1 held at a constant temperature.

The polymerization solvent for use herein may be selected from common solvents and is exemplified by ethers, esters, ketones, amides, sulfoxides, alcohols, hydrocarbons, and mixtures of these solvents. The ethers are exemplified by chain ethers such as diethyl ether and glycol ethers (e.g., propylene glycol monomethyl ether (hereinafter also referred to as “PGME”)); and cyclic ethers such as tetrahydrofuran and dioxane. The esters are exemplified by chain esters such as methyl acetate, ethyl acetate, butyl acetate, and ethyl lactate; and glycol ether esters such as propylene glycol monomethyl ether acetate (hereinafter also referred to as “PGMEA”). The ketones are exemplified by acetone, methyl ethyl ketone, methyl isobutyl ketone, and cyclohexanone. The amides are exemplified by N,N-dimethylacetamide and N,N-dimethylformamide. The sulfoxides are exemplified by dimethyl sulfoxide. The alcohols are exemplified by methanol, ethanol, and propanol. The hydrocarbons are exemplified by aromatic hydrocarbons such as benzene, toluene, and xylenes; aliphatic hydrocarbons such as hexane; and alicyclic hydrocarbons such as cyclohexane. The polymerization initiator may be selected from common polymerization initiators. The polymerization may be performed at a temperature of typically from about 30° C. to about 150° C., preferably from 50° C. to 120° C., and particularly preferably from 60° C. to 100° C.

The polymer compound prepared by polymerization may be subjected to precipitation or reprecipitation treatment. A solvent for use in the precipitation or reprecipitation may be at least one of an organic solvent and water, may be a solvent mixture containing two or more different organic solvents, or may be a solvent mixture containing water and one or more organic solvents. The organic solvents for use as or in the precipitation or reprecipitation solvent are exemplified by hydrocarbons, halogenated hydrocarbons, nitro compounds, nitriles, ethers, ketones, esters, carbonates, alcohols, carboxylic acids, and mixtures of these solvents. The hydrocarbons are exemplified by aliphatic hydrocarbons such as pentane, hexane, heptane, and octane; alicyclic hydrocarbons such as cyclohexane and methylcyclohexane; and aromatic hydrocarbons such as benzene, toluene, and xylenes. The halogenated hydrocarbons are exemplified by halogenated aliphatic hydrocarbons such as methylene chloride, chloroform, and carbon tetrachloride; and halogenated aromatic hydrocarbons such as chlorobenzene and dichlorobenzenes. The nitro compounds are exemplified by nitromethane and nitroethane. The nitriles are exemplified by acetonitrile and benzonitrile. The ethers are exemplified by chain ethers such as diethyl ether, diisopropyl ether, and dimethoxyethane; and cyclic ethers such as tetrahydrofuran and dioxane. The ketones are exemplified by acetone, methyl ethyl ketone, and diisobutyl ketone. The esters are exemplified by ethyl acetate and butyl acetate. The carbonates are exemplified by dimethyl carbonate, diethyl carbonate, ethylene carbonate, and propylene carbonate. The alcohols are exemplified by methanol, ethanol, propanol, isopropyl alcohol, and butanol. The carboxylic acids are exemplified by acetic acid.

The organic solvent for use as or in the precipitation or reprecipitation solvent is preferably a solvent including a hydrocarbon (in particular, an aliphatic hydrocarbon such as hexane). The solvent including a hydrocarbon may have a ratio (by weight) of the hydrocarbon (e.g., aliphatic hydrocarbon such as hexane) to another solvent of typically from about 10:90 to about 99:1, preferably from 30:70 to 98:2, and particularly preferably from 50:50 to 97:3.

The polymer compound undergone the precipitation or reprecipitation treatment may further be subjected to repulping treatment and/or rinsing treatment as needed. Thereafter the polymer compound is preferably subjected to drying treatment after removing the solvent therefrom typically by decantation or filtration. The polymer compound may be dried at a temperature of typically from about 20° C. to about 120° C. and preferably from 30° C. to 100° C. The drying is preferably performed under reduced pressure at typically about 200 mmHg (26.6 kPa) or lower, and particularly preferably 100 mmHg (13.3 kPa) or lower.

In a preferred embodiment, the polymer compound undergone the precipitation or reprecipitation treatment is redissolved in an organic solvent to give a resin solution having a concentration of the polymer compound of from about 10 to about 40 percent by weight; and the resulting resin solution is subjected to the filtering step. The organic solvent is exemplified by the ethers, esters, ketones, and mixtures of these solvents, as exemplified as the polymerization solvent. Among them, preferred are PGME, PGMEA, ethyl lactate, methyl isobutyl ketone, methyl amyl ketone, cyclohexanone, and mixtures of these solvents. In particular, solvents advantageously usable are solvents containing PGMEA (e.g., in a content of 50 percent by weight or more), such as a single solvent of PGMEA, a PGMEA-PGME solvent mixture, a PGMEA-ethyl lactate solvent mixture, and a PGMEA-cyclohexanone solvent mixture.

Before subjected to the filtration treatment, the resin solution prepared by redissolution may be concentrated so as to distill off a low-boiling solvent from the resin solution. The low-boiling solvent includes a solvent used as any of the polymerization solvent, extraction solvent, precipitation solvent, repulping solvent, and rinsing solvent. In an embodiment, the resin solution prepared by redissolution contains such a low-boiling solvent typically when the redissolution is performed without the drying step. In particular in this embodiment, the method preferably includes the concentration step. In the concentration step, the resin solution is preferably concentrated to a concentration of the polymer compound of from about 10 to about 40 percent by weight. The concentration may be performed at normal atmospheric pressure or under reduced pressure.

The polymer compound prepared typically through steps or processes such as the polymerization step and precipitation or reprecipitation treatment is redissolved in an organic solvent to form a resin solution, and the resin solution is subjected to the filtering step. In the method according to the present invention, the resin solution is filtered in the filtering step using a filter, where the filter is approximately devoid of strongly acidic cation-exchange groups and develops a positive zeta potential.

The filter develops a positive zeta potential with respect to a charged substance in a liquid passing therethrough. The filter can adsorb metal components (e.g., Fe and Na) in the substance under filtration to remove the metal components from the substance. The filter is approximately devoid of strongly acidic cation-exchange groups (e.g., —SO₃H).

The filter may be made typically of a material selected from resins, cellulose, perlite, diatomaceous earth, and glass fibers.

The filter may have a pore size of typically from about 0.02 to about 5.0 μm and preferably from 0.04 to 1.0 μm.

The filtration may be performed at a temperature of typically from about 0° C. to about 80° C., preferably from 10° C. to 60° C., and particularly preferably from 20° C. to 50° C.

The filtration may be performed at a flow rate of typically from about 0.01 to about 100 kg/min/m², preferably from 0.1 to 30 kg/min/m², and particularly preferably from 0.5 to 10 kg/min/m².

The filter for use in the present invention may be advantageously selected from commercial products available typically under the trade names of Zeta Plus GN Grade and ELECTROPORE (each from Sumitomo 3M Limited); and the trade name of Posidyne (from Nihon Pall Ltd.).

By the present invention, the filtration treatment is performed in the filtering step using the filter under the conditions. This enables the removal of metal components, still inhibits the leaving of an acid-leaving group in the polymer compound from leaving with time, and enables the production of a polymer compound that has very low contents of metal components and exhibits excellent storage stability. The leaving of the acid-leaving group is triggered by partial hydrolysis of a polar group in the polymer compound. The polar group is exemplified by lactone (in particular, lactone containing one or more electron-withdrawing groups such as cyano and trifluoromethyl), sultone (—S(═O)₂—O—), and acid anhydride (—C(═O)—O—C(═O)—) moieties or groups.

Typically, the resin solution after the filtration treatment may have a sodium content (based on resin solids content) of 20 ppb or less, preferably 15 ppb or less, and particularly preferably 10 ppb or less) and an iron content (based on resin solids content) of 10 ppb or less, preferably 8 ppb or less, and particularly preferably 5 ppb or less.

Assume that the resin solution containing the polymer compound before subjected to the filtering step is heated at 60° C., and that it takes a time (T₀) for the resin solution to have an acid value of greater than 0.05 mmol/g in terms of solids content of the polymer compound. Further assume that the resin solution containing the polymer compound after subjected to the filtering step is heated at 60° C., and that it takes a time (T₁) for the resin solution to have an acid value of greater than 0.05 mmol/g in terms of solids content of the polymer compound. In this case, T₀ minus T₁ is preferably 80 hours or less, particularly preferably 50 hours or less, and most preferably 30 hours or less.

Photoresist Resin Composition

The photoresist resin composition according to an embodiment of the present invention includes the polymer compound, a photoacid generator, and an organic solvent (i.e., a photoresist solvent).

The photoacid generator may be selected from common compounds that efficiently generate an acid upon exposure (light irradiation). Such compounds are exemplified by diazonium salts; iodonium salts such as diphenyliodo hexafluorophosphate; sulfonium salts such as triphenylsulfonium hexafluoroantimonate, triphenylsulfonium hexafluorophosphate, and triphenylsulfonium methanesulfonate; sulfonic acid esters such as 1-phenyl-1-(4-methylphenyl)sulfonyloxy-1-benzoylmethane, 1,2,3-trisulfonyloxymethylbenzene, 1,3-dinitro-2-(4-phenylsulfonyloxymethyl)benzene, and 1-phenyl-1-(4-methylphenylsulfonyloxymethyl)-1-hydroxy-1-benzoylmethane; oxathiazole derivatives; s-triazine derivatives; disulfone derivatives such as diphenyl disulfone; imide compounds; oxime sulfonates; diazonaphthoquinone; and benzoin tosylate. Each of them may be used alone or in combination as the photoacid generator.

The photoresist resin composition may include the photoacid generator in an amount of typically from about 0.1 to about 30 parts by weight, preferably from 1 to 25 parts by weight, and particularly preferably from 2 to 20 parts by weight, per 100 parts by weight of the polymer compound. The amount may be selected as appropriate depending typically on the strength of an acid to be generated upon light irradiation and proportions of individual monomer units (constitutional repeating units) in the polymer compound.

The organic solvent is exemplified by ethers, esters, and ketones. The ethers are exemplified by chain ethers including glycol ethers such as PGME; and cyclic ethers such as dioxane. The esters are exemplified by chain esters such as methyl acetate, ethyl acetate, butyl acetate, and ethyl lactate; cyclic esters such as γ-butyrolactone; and glycol ether esters such as PGMEA. The ketones are exemplified by methyl ethyl ketone, methyl isobutyl ketone, and cyclohexanone. Each of them may be used alone or in combination as the organic solvent. In particular, the photoresist resin composition herein preferably include at least one solvent selected from the group consisting of PGMEA, PGME, ethyl lactate, γ-butyrolactone, and cyclohexanone.

The photoresist resin composition may include the organic solvent in such a content that the polymer compound concentration be typically from about 1 to about 20 percent by weight, preferably from 2 to 15 percent by weight, and particularly preferably from 3 to 15 percent by weight. The organic solvent content may be selected as appropriate depending typically on the thickness of a resist film to be formed.

The photoresist resin composition according to the present invention may further include one or more additional components in addition to the polymer compound, the photoacid generator, and the organic solvent. Such additional components are exemplified by basic compounds such as triethylamine, 1,8-diazabicyclo[5.4.0]-7-undecene (DBU), and 1,5-diazabicyclo[4.3.0]-5-nonene (DBN), where these basic compounds are used for improving post-exposure delay stability (post-exposure temporal stability) between an exposure step and a post-exposure baking step; additive resins for improving resist performance; surfactants for higher coatability upon film formation; dissolution inhibitors for controlling the solubility upon development; stabilizers; plasticizers; photosensitizers; and light absorbers.

### EXAMPLES

The present invention will be illustrated in further detail with reference to several examples below. It should be noted, however, that the examples are by no means intended to limit the scope of the present invention.

The weight-average molecular weight (Mw) and number-average molecular weight (Mn) of a polymer compound were determined by GPC measurement (with a gel permeation chromatograph) using tetrahydrofuran as a solvent. In the measurement, a polystyrene was used as a reference standard, and a refractive index detector (RI detector) was used as a detector. The GPC measurement was performed using three columns KF-806L (supplied by Showa Denko K.K.) coupled in series at a column temperature of 40° C., an RI temperature of 40° C., and a tetrahydrofuran flow rate of 0.8 mL/min. The molecular weight distribution (Mw/Mn) was calculated from the measured values.

### Preparation Example 1

### Production of Resin Solution 1

In a nitrogen atmosphere, 595.0 g of cyclohexanone was placed in a round-bottomed flask equipped with a reflux condenser, a stirring bar, a three-way stopcock, and a thermometer. While being held at a temperature of 100° C. with stirring, the cyclohexanone was combined with a monomer solution added dropwise at a constant rate over 6 hours. The monomer solution was a mixture including 118.2 g (0.478 mol) of 1-cyano-5-methacryloyloxy-3-oxatricyclo[4.2.1.0^{4,8}]nonan-2-one, 56.5 g (0.239 mol) of 1-hydroxy-3-methacryloyloxyadamantane, 125.4 g (0.478 mol) of 1-(1-methacryloyloxy-1-methylethyl)adamantane, 7.50 g of dimethyl 2,2′-azobisisobutyrate (trade name V-601, supplied by Wako Pure Chemical Industries, Ltd.), and 1105.0 g of cyclohexanone. After the completion of dropwise addition, the resulting mixture was further stirred for 2 hours. After the completion of polymerization reaction, the reaction solution (reaction mixture) was filtered through a filter with a pore size of 0.1 μm, and added dropwise to seven times the amount of a 9:1 (by weight) mixture of hexane and ethyl acetate with stirring to form precipitates. The precipitates were separated and collected by filtration, dried, and yielded 247.5 g of a polymer compound including a monomer unit represented by Formula (1) below. The polymer compound had a weight-average molecular weight (Mw) of 8300 and a molecular weight distribution (Mw/Mn) of 1.88.

The prepared polymer compound was dissolved in PGMEA to a polymer concentration of 15% and yielded a resin solution 1.

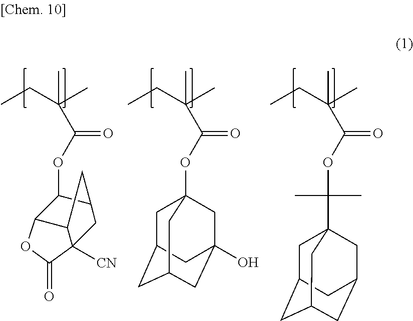

### Preparation Example 2

### Production of Resin Solution 2

The procedure in Example 1 was performed, except for using, as monomer components, 121.3 g (0.470 mol) of 5-methacryloyloxy-3-oxa-2-thiatricyclo[4.2.1.0^{4,8}]nonane-2,2-dione, 55.5 g (0.235 mol) of 1-hydroxy-3-methacryloyloxyadamantane, and 123.2 g (0.470 mol) of 1-(1-methacryloyloxy-1-methylethyl)adamantane. This yielded 257.2 g of a polymer compound including a monomer unit represented by Formula (2) below. The polymer compound had a weight-average molecular weight (Mw) of 8200 and a molecular weight distribution (Mw/Mn) of 1.91.

The prepared polymer compound was dissolved in PGMEA to a polymer concentration of 15% and yielded a resin solution 2.

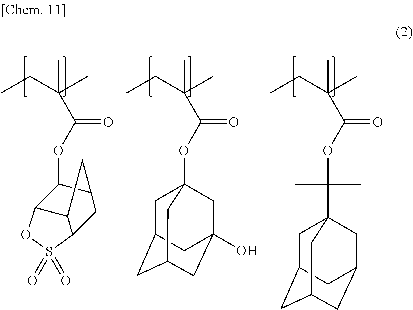

### Preparation Example 3

### Production of Resin Solution 3

The procedure in Example 1 was performed, except for using, as monomer components, 133.6 g (0.438 mol) of 1-cyano-5-(2-methacryloyloxyacetoxy)-3-oxatricyclo[4.2.1.0^{4,8}]nonan-2-one, 51.7 g (0.219 mol) of 1-hydroxy-3-methacryloyloxyadamantane, and 114.7 g (0.438 mol) of 1-(1-methacryloyloxy-1-methylethyl)adamantane. This yielded 254.4 g of a polymer compound including a monomer unit represented by Formula (3) below. The polymer compound had a weight-average molecular weight (Mw) of 9000 and a molecular weight distribution (Mw/Mn) of 1.83.

The prepared polymer compound was dissolved in PGMEA to a polymer concentration of 15% and yielded a resin solution 3.

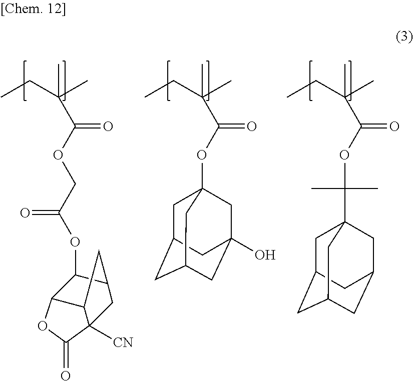

### Preparation Example 4

### Production of Resin Solution 4

The procedure in Example 1 was performed, except for using, as monomer components, 131.1 g (0.430 mol) of 1-cyano-5-(2-methacryloyloxyacetoxy)-3-oxatricyclo[4.2.1.0^{4,8}]nonan-2-one and 168.9 g (0.645 mol) of 1-(1-methacryloyloxy-1-methylethyl)adamantane. This yielded 239.8 g of a polymer compound including a monomer unit represented by Formula (4) below. The polymer compound had a weight-average molecular weight (Mw) of 7500 and a molecular weight distribution (Mw/Mn) of 1.80.

The prepared polymer compound was dissolved in PGMEA to a polymer concentration of 15% and yielded a resin solution 4.

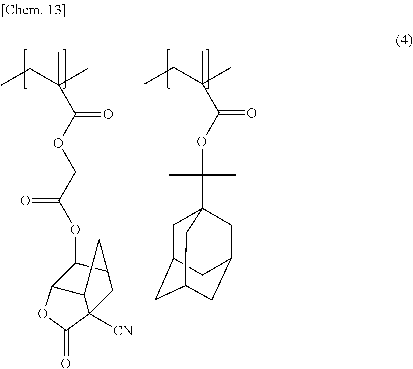

### Preparation Example 5

### Production of Resin Solution 5

The procedure in Example 1 was performed, except for using, as monomer components, 158.3 g (0.519 mol) of 1-cyano-5-(2-methacryloyloxyacetoxy)-3-oxatricyclo[4.2.1.0^{4,8}]nonan-2-one and 141.7 g (0.779 mol) of 2-ethyl-2-methacryloyloxycyclopentane. This yielded 227.4 g of a polymer compound including a monomer unit represented by Formula (5) below. The polymer compound had a weight-average molecular weight (Mw) of 6800 and a molecular weight distribution (Mw/Mn) of 1.75.

The prepared polymer compound was dissolved in PGMEA to a polymer concentration of 15% and yielded a resin solution 5.

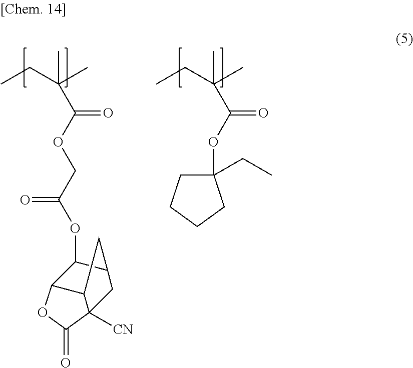

### Preparation Example 6

### Production of Resin Solution 6

The procedure in Example 1 was performed, except for using, as monomer components, 136.2 g (0.431 mol) of 5-(2-methacryloyloxyacetoxy)-3-oxa-2-thiatricyclo[4.2.1.0^{4,8}]nonane-2,2-dione, 50.9 g (0.216 mol) of 1-hydroxy-3-methacryloyloxyadamantane, and 112.9 g (0.431 mol) of 1-(1-methacryloyloxy-1-methylethyl)adamantane. This yielded 247.0 g of a polymer compound including a monomer unit represented by Formula (6) below. The polymer compound had a weight-average molecular weight (Mw) of 8500 and a molecular weight distribution (Mw/Mn) of 1.91.

The prepared polymer compound was dissolved in PGMEA to a polymer concentration of 15% and yielded a resin solution 6.

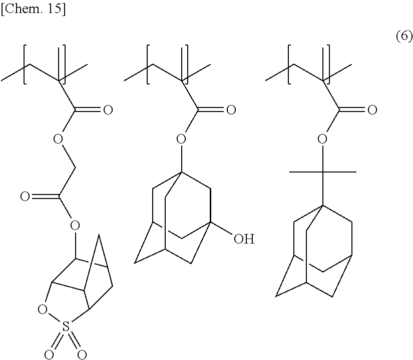

### Preparation Example 7

### Production of Resin Solution 7

In a nitrogen atmosphere, 357.0 g of PGMEA and 238.0 g of PGME were placed in a round-bottomed flask equipped with a reflux condenser, a stirring bar, a three-way stopcock, and a thermometer. While being held at a temperature of 100° C. with stirring, the mixture was combined with a monomer solution added dropwise at a constant rate over 6 hours. The monomer solution was a mixture including 119.0 g (0.476 mol) of 5-methacryloyloxynorbornane-2,3-dicarboxylic anhydride, 56.2 g (0.238 mol) of 1-hydroxy-3-methacryloyloxyadamantane, 124.8 g (0.476 mol) of 1-(1-methacryloyloxy-1-methylethyl)adamantane, 7.50 g of dimethyl 2,2′-azobisisobutyrate (trade name V-601, supplied by Wako Pure Chemical Industries, Ltd.), 663.0 g of PGMEA, and 442.0 g of PGME. After the completion of dropwise addition, the resulting mixture was further stirred for 2 hours. After the completion of polymerization reaction, the reaction solution (reaction mixture) was filtered through a filter with a pore size of 0.1 μm and added dropwise to seven times the amount of a 9:1 (by weight) mixture of hexane and ethyl acetate with stirring to form precipitates. The precipitates were separated and collected by filtration, dried, and yielded 243.5 g of a polymer compound including a monomer unit represented by Formula (7) below. The polymer compound had a weight-average molecular weight (Mw) of 8800 and a molecular weight distribution (Mw/Mn) of 1.90.

The prepared polymer compound was dissolved in PGMEA to a polymer concentration of 15% and yielded a resin solution 7.

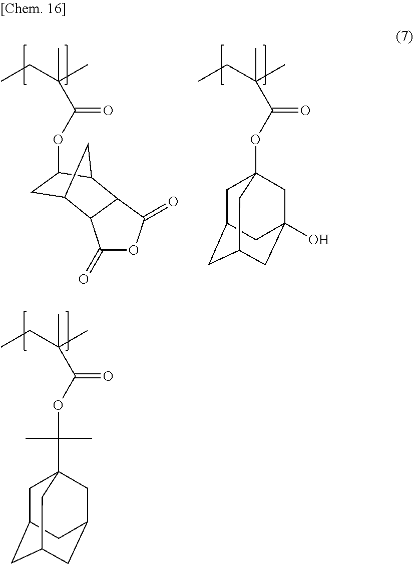

### Preparation Example 8

### Production of Resin Solution 8

The procedure in Example 1 was performed, except for using, as monomer components, 129.9 g (0.448 mol) of 1-trifluoromethyl-5-methacryloyloxy-3-oxatricyclo[4.2.1.0^{4,8}]nonan-2-one, 52.8 g (0.224 mol) of 1-hydroxy-3-methacryloyloxyadamantane, and 117.3 g (0.448 mol) of 1-(1-methacryloyloxy-1-methylethyl)adamantane. This yielded 255.3 g of a polymer compound including a monomer unit represented by Formula (8) below. The polymer compound had a weight-average molecular weight (Mw) of 8000 and a molecular weight distribution (Mw/Mn) of 1.95.

The prepared polymer compound was dissolved in PGMEA to a polymer concentration of 15% and yielded a resin solution 8.

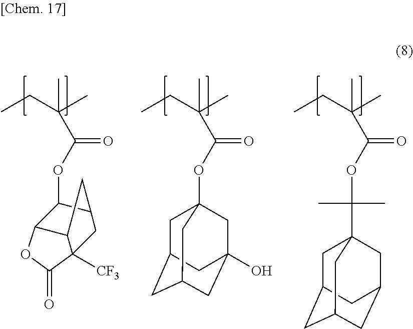

### Example 1

The resin solution 1 prepared in Preparation Example 1 was subjected to filtration treatment using a filter [trade name Zeta Plus 020GN, supplied by Sumitomo 3M Limited and having a having a pore size of 0.2 μm] at a filtration flow rate of 5 kg/min/m² and a filtration temperature of 23° C. This yielded a resin solution after filtration treatment.

### Example 2

Filtration treatment was performed by the procedure of Example 1, except for using the resin solution 2 prepared in Preparation Example 2, instead of the resin solution 1 prepared in Preparation Example 1. This yielded a resin solution after filtration treatment.

### Example 3

Filtration treatment was performed by the procedure of Example 1, except for using the resin solution 3 prepared in Preparation Example 3, instead of the resin solution 1 prepared in Preparation Example 1. This yielded a resin solution after filtration treatment.

### Example 4

Filtration treatment was performed by the procedure of Example 1, except for using the resin solution 4 prepared in Preparation Example 4, instead of the resin solution 1 prepared in Preparation Example 1. This yielded a resin solution after filtration treatment.

### Example 5

Filtration treatment was performed by the procedure of Example 1, except for using the resin solution 5 prepared in Preparation Example 5, instead of the resin solution 1 prepared in Preparation Example 1. This yielded a resin solution after filtration treatment.

### Example 6

Filtration treatment was performed by the procedure of Example 1, except for using the resin solution 6 prepared in Preparation Example 6, instead of the resin solution 1 prepared in Preparation Example 1. This yielded a resin solution after filtration treatment.

### Example 7

Filtration treatment was performed by the procedure of Example 1, except for using the resin solution 7 prepared in Preparation Example 7, instead of the resin solution 1 prepared in Preparation Example 1. This yielded a resin solution after filtration treatment.

### Example 8

Filtration treatment was performed by the procedure of Example 1, except for using the resin solution 8 prepared in Preparation Example 8, instead of the resin solution 1 prepared in Preparation Example 1. This yielded a resin solution after filtration treatment.

### Example 9

The resin solution 1 prepared in Preparation Example 1 was subjected to filtration treatment using a filter [trade name ELECTROPORE, supplied by Sumitomo 3M Limited and having a pore size of 0.04 μm] at a filtration flow rate of 5 kg/min/m² and a filtration temperature of 23° C. This yielded a resin solution after filtration treatment.

### Example 10

Filtration treatment was performed by the procedure of Example 9, except for using the resin solution 2 prepared in Preparation Example 2, instead of the resin solution 1 prepared in Preparation Example 1. This yielded a resin solution after filtration treatment.

### Comparative Example 1

The resin solution 1 prepared in Preparation Example 1 was subjected to filtration treatment using a filter containing a strongly acidic cation-exchange group [trade name Zeta Plus 40QSH, supplied by Sumitomo 3M Limited and having a pore size of 0.4 μm] at a filtration flow rate of 5 kg/min/m² and a filtration temperature of 23° C. This yielded a resin solution after filtration treatment.

### Comparative Example 2

The resin solution 1 prepared in Preparation Example 1 was subjected to filtration treatment using a filter containing a strongly acidic cation-exchange group [trade name Protego, supplied by Nihon Entegris K.K. and having a pore size of 0.05 μm] at a filtration flow rate of 5 kg/min/m² and a filtration temperature of 23° C. This yielded a resin solution after filtration treatment.

### Comparative Example 3

The resin solution 1 prepared in Preparation Example 1 was subjected to filtration treatment using a filter containing a strongly acidic cation-exchange group [trade name IonKleen SL, supplied by Nihon Pall Ltd.] at a filtration flow rate of 5 kg/min/m² and a filtration temperature of 23° C. This yielded a resin solution after filtration treatment.

### Comparative Example 4

The resin solution 2 prepared in Preparation Example 2 was subjected to filtration treatment using a filter containing a strongly acidic cation-exchange group [trade name Protego, supplied by Nihon Entegris K.K. and having a pore size of 0.05 μm] at a filtration flow rate of 5 kg/min/m² and a filtration temperature of 23° C. This yielded a resin solution after filtration treatment.

### Comparative Example 5

The resin solution 4 prepared in Preparation Example 4 was subjected to filtration treatment using a filter containing a strongly acidic cation-exchange group [trade name IonKleen SL, supplied by Nihon Pall Ltd.] at a filtration flow rate of 5 kg/min/m² and a filtration temperature of 23° C. This yielded a resin solution after filtration treatment.

### Comparative Example 6

The resin solution 5 prepared in Preparation Example 5 was subjected to filtration treatment using a filter containing a strongly acidic cation-exchange group [trade name IonKleen SL, supplied by Nihon Pall Ltd.] at a filtration flow rate of 5 kg/min/m² and a filtration temperature of 23° C. This yielded a resin solution after filtration treatment.

The resin solutions prepared in the preparation examples and the resin solutions after filtration treatment prepared in the examples and comparative examples were subjected to measurements of metal contents (based on resin solids content) using an inductively-coupled plasma mass spectrometer. Independently, the resin solutions prepared in the preparation examples and the resin solutions after filtration treatment prepared in the examples and comparative examples were each heated at 60° C., and times taken for the resin solutions to have an acid value of greater than 0.05 mmol/g were measured. The measurements were performed so as to compare storage stability of the resin solutions between before and after the filtration treatment. Results are indicated together in a table below.

The acid value was measured by neutralization titration with NaOH. Specifically, 0.5 g of a sample resin solution containing a resin (polymer) in a concentration of 15 percent by weight in PGMEA was weighed and combined with 54 mL of tetrahydrofuran (THF) and 6 mL of water. The solution was further combined with 0.05 g of an ethanol solution containing 1 percent by volume of phenolphthalein as an indicator. The resulting solution was titrated, with stirring, with a 0.1 mol/L NaOH aqueous solution. At a point when the solution changed in color from colorless to pink was defined as the end point of titration. The acid value was calculated according to an expression as follows:

Acid value (mmol/g)=[(B×0.1)/(A×C)]×100

where A represents the weight (g) of the test portion; B represents the amount (mL) of the 0.1 mol/L NaOH aqueous solution added dropwise to the end point; and C represents the resin concentration (percent by weight) in the test portion.

TABLE 1

| | | | | | | Heating time (hr) taken for resin | | |
|---|---|---|---|---|---|---|---|---|
| | | Metal removability (ppb) | | | | solution to have acid value | | |
| | Resin | Before filtration | | After filtration | | greater than 0.05 mmol/g | | |
| | solution | treatment | | treatment | | Before filtration | After filtration | |
| | number | Na | Fe | Na | Fe | treatment (T₀) | treatment (T₁) | T₀ − T₁ |
| Example 1 | 1 | 165 | 33 | 3 | 3 | 288 | 288 | 0 |
| Example 2 | 2 | 152 | 27 | 5 | 5 | 121 | 121 | 0 |
| Example 3 | 3 | 89 | 25 | 2 | 3 | 238 | 238 | 0 |
| Example 4 | 4 | 231 | 18 | 5 | 2 | 167 | 167 | 0 |
| Example 5 | 5 | 180 | 45 | 3 | 3 | 119 | 119 | 0 |
| Example 6 | 6 | 130 | 22 | 6 | 2 | 120 | 120 | 0 |
| Example 7 | 7 | 205 | 19 | 7 | 5 | 72 | 72 | 0 |
| Example 8 | 8 | 113 | 41 | 8 | 6 | 145 | 145 | 0 |
| Example 9 | 1 | 165 | 33 | 2 | 3 | 285 | 285 | 0 |
| Example 10 | 2 | 152 | 27 | 2 | 1 | 121 | 121 | 0 |
| Comparative | 1 | 165 | 33 | 2 | 4 | 286 | 95 | 191 |
| Example 1 | | | | | | | | |
| Comparative | 1 | 165 | 33 | 5 | 5 | 288 | 73 | 215 |
| Example 2 | | | | | | | | |
| Comparative | 1 | 165 | 33 | 7 | 3 | 288 | 119 | 169 |
| Example 3 | | | | | | | | |
| Comparative | 2 | 152 | 27 | 3 | 2 | 118 | 24 | 94 |
| Example 4 | | | | | | | | |
| Comparative | 4 | 231 | 18 | 4 | 2 | 170 | 48 | 122 |
| Example 5 | | | | | | | | |
| Comparative | 5 | 180 | 45 | 2 | 4 | 120 | 24 | 96 |
| Example 6 | | | | | | | | |

### INDUSTRIAL APPLICABILITY

When a polymer compound is prepared by polymerization of a monomer mixture, the method for producing a polymer compound according to the present invention can remove metal components, such as sodium and iron, from the polymer compound and still inhibits an acid-leaving group in the polymer compound from leaving with time. The metal components cause deterioration in electrical properties typically of semiconductor devices. The method can give a polymer compound that exhibits excellent storage stability and has very low contents of metal components such as sodium and iron.

The polymer compound according to the present invention exhibits excellent storage stability, has very low contents of metal components such as sodium and iron, and is advantageously usable as a resist polymer for ArF exposure. The polymer compound according to the present invention contributes to the production of a semiconductor device that has excellent electrical properties.

1. A method for producing a polymer compound, the method comprising the step of filtering a resin solution comprising a polymer compound through a filter,
the filter being approximately devoid of strongly acidic cation-exchange groups and developing a positive zeta potential,
the polymer compound comprising:
a monomer unit (a); and
a monomer unit (b) comprising a group capable of releasing a moiety thereof by an action of an acid to develop solubility in an alkali,
the monomer unit (a) comprising at least one monomer unit selected from the group consisting of monomer units represented by Formulae (a1) to (a3): 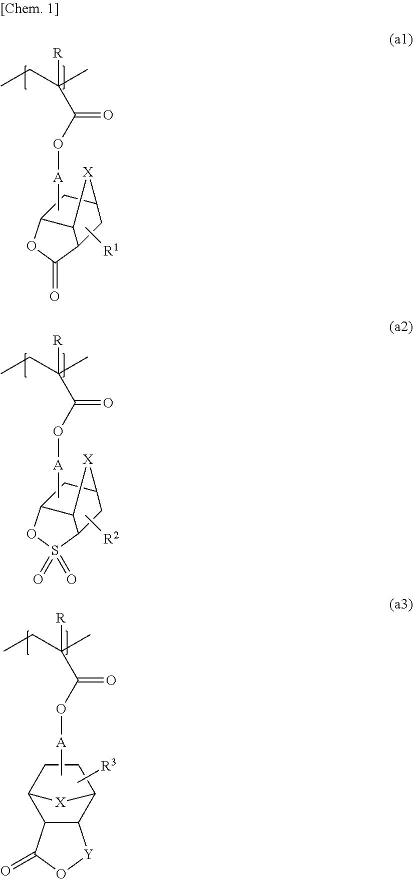
wherein R is, independently in each occurrence, selected from hydrogen, halogen, and optionally halogenated C₁-C₆ alkyl; A is, independently in each occurrence, selected from a single bond and a linkage group; X is, independently in each occurrence, selected from non-bond, methylene, ethylene, oxygen, and sulfur; Y is selected from methylene and carbonyl; and R¹ to R³ are, identically or differently, selected from hydrogen, fluorine, optionally fluorinated alkyl, optionally protected hydroxyl, optionally protected hydroxyalkyl, optionally protected carboxy, and cyano.

2. The method for producing a polymer compound, according to claim 1,
wherein the resin solution undergone the filtering step has a sodium content (based on resin solids content) of 20 ppb or less and an iron content (based on resin solids content) of 10 ppb or less.

3. The method for producing a polymer compound, according to claim 1,
wherein times T₀ and T₁ meet a condition specified by formula:
T₀−T₁≦80
wherein T₀ represents a time taken for the resin solution before subjected to the filtering step to have an acid value of greater than 0.05 mmol/g upon heating at 60° C.; and T₁ represents a time taken for the resin solution after subjected to the filtering step to have an acid value of greater than 0.05 mmol/g upon heating at 60° C.

4. The method for producing a polymer compound, according to claim 1,
wherein the monomer unit (b) comprises at least one monomer unit selected from the group consisting of monomer units represented by Formulae (b1) to (b4): 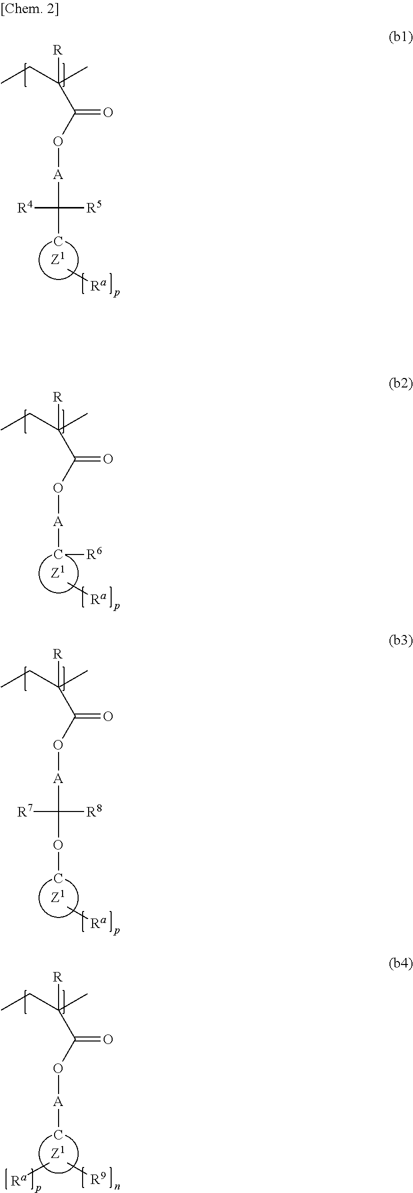
wherein R is, independently in each occurrence, selected from hydrogen, halogen, and optionally halogenated C₁-C₆ alkyl; A is, independently in each occurrence, selected from a single bond and a linkage group; R⁴ to R⁶ represent, identically or differently, optionally substituted C₁-C₆ alkyl; R⁷ and R⁸ are, identically or differently, selected from hydrogen and optionally substituted C₁-C₆ alkyl; R⁹ represents, independently in each occurrence, a —COOR^{c} group, where R^{c} is, independently in each occurrence, selected from an optionally substituted tertiary hydrocarbon group, tetrahydrofuranyl, tetrahydropyranyl, and oxepanyl; n represents an integer of from 1 to 3; R^{a} is a substituent bonded to Ring Z¹ and is, independently in each occurrence, selected from oxo, alkyl, optionally protected hydroxyl, optionally protected hydroxyalkyl, and optionally protected carboxy; p represents, independently in each occurrence, an integer of from 0 to 3, where, when p is 2 or 3, two or three occurrences of R^{a} may be identical or different; and Ring Z¹ represents, independently in each occurrence, a C₃-C₂₀ alicyclic hydrocarbon ring.

5. The method for producing a polymer compound, according to claim 1,
wherein the polymer compound further comprises, in addition to the monomer units (a) and (b), a monomer unit (c) represented by Formula (c1): 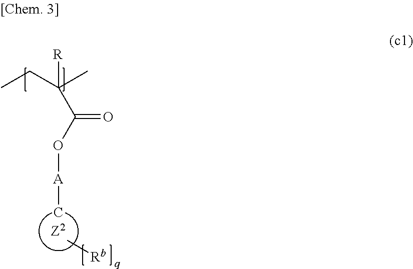
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

6. A polymer compound produced by the method according to claim 1.

7. The polymer compound according to claim 6,
wherein the polymer compound has a weight-average molecular weight of from 1000 to 50000.

8. The polymer compound according to claim 6,
wherein the polymer compound has a molecular weight distribution of from 1.0 to 3.0, where the molecular weight distribution is a ratio of the weight-average molecular weight to a number-average molecular weight.

9. A photoresist resin composition comprising:
the polymer compound according to claim 6;
a photoacid generator; and
an organic solvent.

10. The method for producing a polymer compound, according to claim 2,
wherein times T₀ and T₁ meet a condition specified by formula:
T₀−T₁≦80
wherein T₀ represents a time taken for the resin solution before subjected to the filtering step to have an acid value of greater than 0.05 mmol/g upon heating at 60° C.; and T₁ represents a time taken for the resin solution after subjected to the filtering step to have an acid value of greater than 0.05 mmol/g upon heating at 60° C.

11. The method for producing a polymer compound, according to claim 2,
wherein the monomer unit (b) comprises at least one monomer unit selected from the group consisting of monomer units represented by Formulae (b1) to (b4): 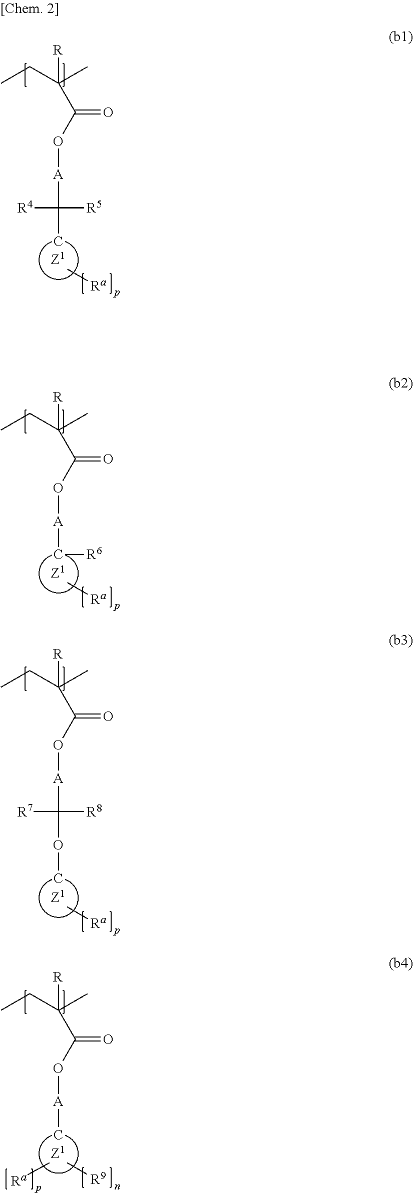
wherein R is, independently in each occurrence, selected from hydrogen, halogen, and optionally halogenated C₁-C₆ alkyl; A is, independently in each occurrence, selected from a single bond and a linkage group; R⁴ to R⁶ represent, identically or differently, optionally substituted C₁-C₆ alkyl; R⁷ and R⁸ are, identically or differently, selected from hydrogen and optionally substituted C₁-C₆ alkyl; R⁹ represents, independently in each occurrence, a —COOR^{c} group, where R^{c} is, independently in each occurrence, selected from an optionally substituted tertiary hydrocarbon group, tetrahydrofuranyl, tetrahydropyranyl, and oxepanyl; n represents an integer of from 1 to 3; R^{a} is a substituent bonded to Ring Z¹ and is, independently in each occurrence, selected from oxo, alkyl, optionally protected hydroxyl, optionally protected hydroxyalkyl, and optionally protected carboxy; p represents, independently in each occurrence, an integer of from 0 to 3, where, when p is 2 or 3, two or three occurrences of R^{a} may be identical or different; and Ring Z¹ represents, independently in each occurrence, a C₃-C₂₀ alicyclic hydrocarbon ring.

12. The method for producing a polymer compound, according to claim 3,
wherein the monomer unit (b) comprises at least one monomer unit selected from the group consisting of monomer units represented by Formulae (b1) to (b4): 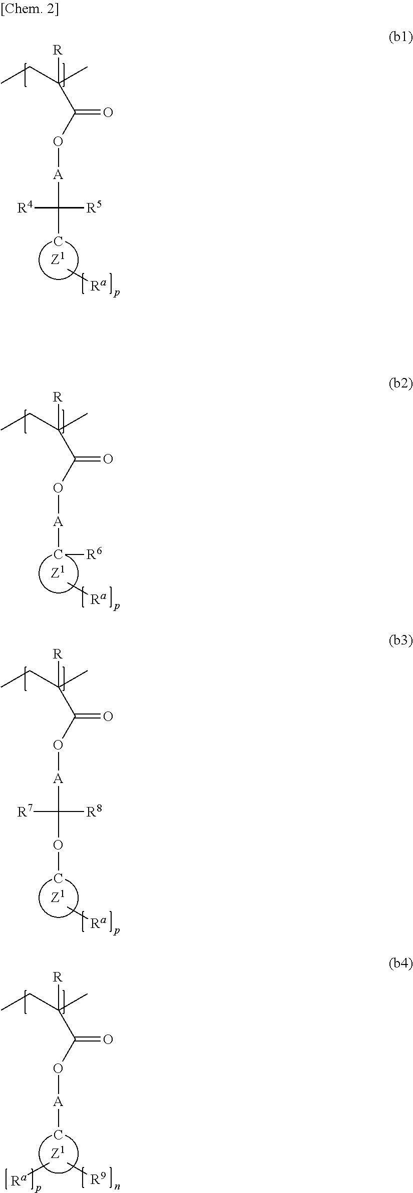
wherein R is, independently in each occurrence, selected from hydrogen, halogen, and optionally halogenated C₁-C₆ alkyl; A is, independently in each occurrence, selected from a single bond and a linkage group; R⁴ to R⁶ represent, identically or differently, optionally substituted C₁-C₆ alkyl; R⁷ and R⁸ are, identically or differently, selected from hydrogen and optionally substituted C₁-C₆ alkyl; R⁹ represents, independently in each occurrence, a —COOR^{c} group, where R^{c} is, independently in each occurrence, selected from an optionally substituted tertiary hydrocarbon group, tetrahydrofuranyl, tetrahydropyranyl, and oxepanyl; n represents an integer of from 1 to 3; R^{a} is a substituent bonded to Ring Z¹ and is, independently in each occurrence, selected from oxo, alkyl, optionally protected hydroxyl, optionally protected hydroxyalkyl, and optionally protected carboxy; p represents, independently in each occurrence, an integer of from 0 to 3, where, when p is 2 or 3, two or three occurrences of R^{a} may be identical or different; and Ring Z¹ represents, independently in each occurrence, a C₃-C₂₀ alicyclic hydrocarbon ring.

13. The method for producing a polymer compound, according to claim 10,
wherein the monomer unit (b) comprises at least one monomer unit selected from the group consisting of monomer units represented by Formulae (b1) to (b4): 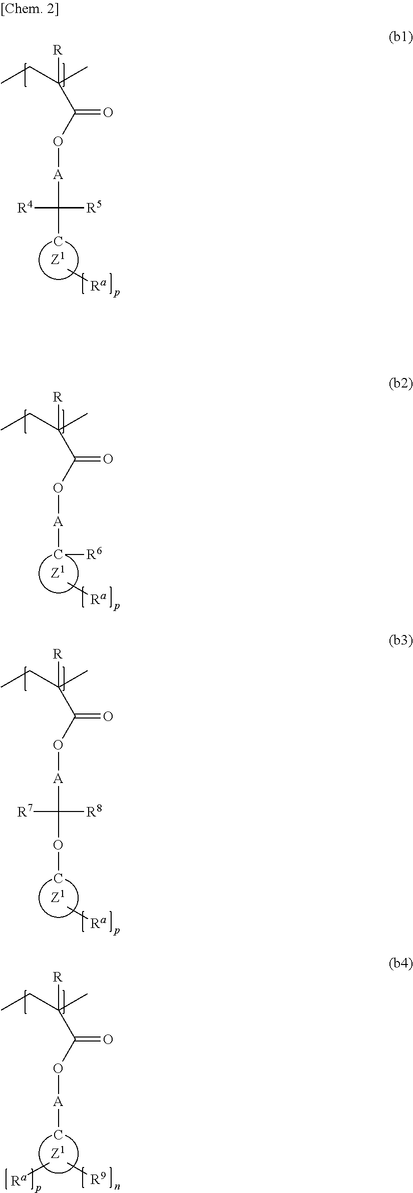
wherein R is, independently in each occurrence, selected from hydrogen, halogen, and optionally halogenated C₁-C₆ alkyl; A is, independently in each occurrence, selected from a single bond and a linkage group; R⁴ to R⁶ represent, identically or differently, optionally substituted C₁-C₆ alkyl; R⁷ and R⁸ are, identically or differently, selected from hydrogen and optionally substituted C₁-C₆ alkyl; R⁹ represents, independently in each occurrence, a —COOR^{c} group, where R^{c} is, independently in each occurrence, selected from an optionally substituted tertiary hydrocarbon group, tetrahydrofuranyl, tetrahydropyranyl, and oxepanyl; n represents an integer of from 1 to 3; R^{a} is a substituent bonded to Ring Z¹ and is, independently in each occurrence, selected from oxo, alkyl, optionally protected hydroxyl, optionally protected hydroxyalkyl, and optionally protected carboxy; p represents, independently in each occurrence, an integer of from 0 to 3, where, when p is 2 or 3, two or three occurrences of R^{a} may be identical or different; and Ring Z¹ represents, independently in each occurrence, a C₃-C₂₀ alicyclic hydrocarbon ring.

14. The method for producing a polymer compound, according to claim 2,
wherein the polymer compound further comprises, in addition to the monomer units (a) and (b), a monomer unit (c) represented by Formula (c1): 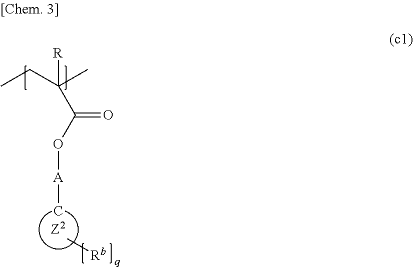
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

15. The method for producing a polymer compound, according to claim 3,
wherein the polymer compound further comprises, in addition to the monomer units (a) and (b), a monomer unit (c) represented by Formula (c1): 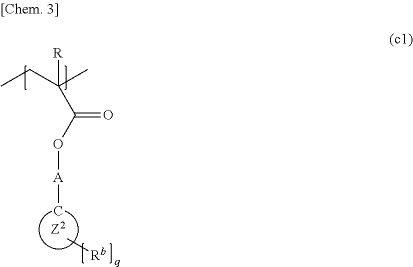
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

16. The method for producing a polymer compound, according to claim 10,
wherein the polymer compound further comprises, in addition to the monomer units (a) and (b), a monomer unit (c) represented by Formula (c1): 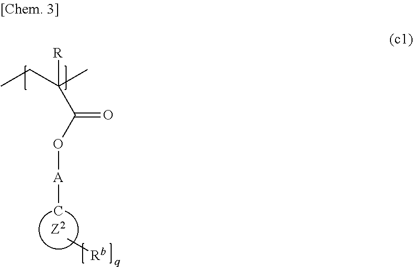
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

17. The method for producing a polymer compound, according to claim 4,
wherein the polymer compound further comprises, in addition to the monomer units (a) and (b), a monomer unit (c) represented by Formula (c1): 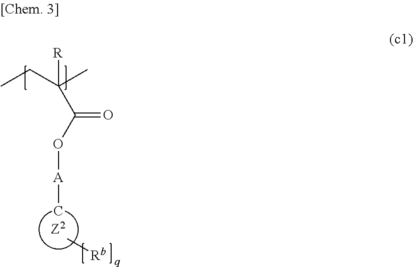
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

18. The method for producing a polymer compound, according to claim 11,
wherein the polymer compound further comprises, in addition to the monomer units (a) and (b), a monomer unit (c) represented by Formula (c1): 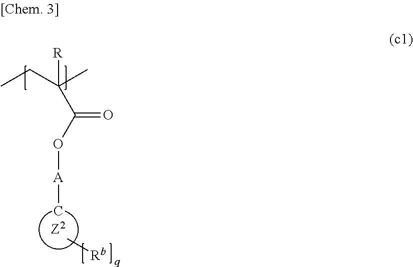
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

19. The method for producing a polymer compound, according to claim 12,
wherein the polymer compound further comprises, in addition to the monomer units (a) and (b), a monomer unit (c) represented by Formula (c1): 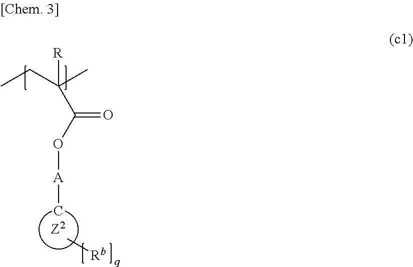
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.

20. The method for producing a polymer compound, according to claim 13,
wherein the polymer compound further comprises, in addition to the monomer units (a) and (b), a monomer unit (c) represented by Formula (c1): 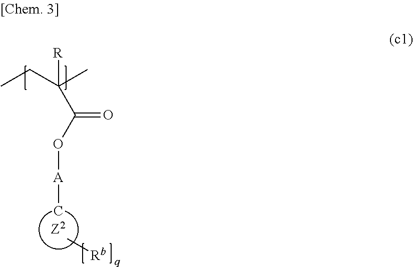
wherein R is selected from hydrogen, halogen, and optionally halogenated C₁-C₆ alkyl; A is selected from a single bond and a linkage group; R^{b} is, independently in each occurrence, selected from optionally protected hydroxyl, optionally protected hydroxyalkyl, optionally protected carboxy, and cyano; q represents an integer of from 1 to 5; and Ring Z² represents a C₆-C₂₀ alicyclic hydrocarbon ring.
